(19) United States
(12) Patent Application Publication
(10) Pub. No.: US 2005/0179918 A1
(43) Pub. Date: Aug. 18, 2005

(54) Color matching system and display device

(75) Inventors: Takashi Kurumisawa, Shiojiri-shi (JP); Katsumi Komagamine, Kagoshima-shi (JP); Masanori Ishida, Kagoshima-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/058,210

(22) Filed: Feb. 16, 2005

(30) Foreign Application Priority Data
Feb. 17, 2004 (JP) 2004-039534

(51) Int. Cl. G06K 15/00; G03F 3/08

(52) U.S. Cl. 358/1.9; 358/2.1; 358/518

(57) ABSTRACT

To provide a color matching system which enables reliably color-matched image data to be displayed on a display device without effort to perform color matching on applications. A color matching system is mounted on, for example, an image display device, and performs color conversion adapted to color characteristics of a display device. A graphics interface, such as a graphics device interface (GDI), generates image creating commands for image data generated according to the operation of an application, and the display image data is generated based on the image creating commands. The display image data is supplied to the display device after the display image data has been subjected to the color conversion by the color management module and the color space adjustment has been performed based on a color attribute file representing the color characteristics of the display device. With this configuration, the display image data adapted to the color reproducibility of the display device is displayed on the display device. Since the color conversion process for color matching is performed not by an application side but instead by the color management at a hardware-dependent portion, such as an OS, a proper color matching is achieved without requiring any intervention from the application side.

### BACKGROUND

Exemplary aspects of the present invention relate to a color matching system to display image data adapted to color characteristics of a display device.

Related art color matching systems correct images of various sources with color characteristics adapted to color spaces of a display device. In general, the related art color matching system performs color conversion among display devices by the use of a color matching structure of an operating system (OS) by an application using an international color consortium (ICC) profile. The ICC profile includes 3×3 matrices or three-dimensional tables, four-dimensional tables, etc., which define the relationship between a standard color space, such as a CIE L*a*b* color system and a CIE XYZ color system, and a device color (RGB or CMYK, for example). On this account, as the implementation of the color matching system is affected by the application itself, it is necessary for application developers to have sufficient knowledge of color matching. In addition, the ICC profile of a monitor, etc. is required to be registered by a user in a default site through the control of the OS. However, since a setting method of the ICC profile is different in each OS, the number of users who can implement the color matching is limited.

### SUMMARY

Since built-in devices installed with color liquid crystal panels (which is a key element in mobile phones), are distributed as finished products, the color matching structure of a high level is frequently not required when the built-in devices reproduce color. However, recently, in addition to realizing an accurate color reproduction of images by the built-in display devices, such as mobile phones installed with cameras, it becomes necessary to reproduce color accurately in other mobile phones and other display devices, such as personal computers (PC) or printers on a network. Thus, other than the techniques to reproduce color in the built-in devices, there is also a prevalent need for techniques to reproduce color by a color matching based on a more general ICC profile.

In consideration of the above and/or other circumstances, exemplary aspects of the present invention provide a color matching system which enables reliably color-matched image data to be displayed on a display device without effort to perform the color matching on applications.

In order to achieve the above, according to one exemplary aspect of the present invention, a color matching system includes a graphics interface to generate image creating commands based on instructions from an application, and a color management module to perform color conversion on display image data based on predetermined color conversion reference data. The color management module includes a color management module driver to perform the color conversion on the display image data and a color management module entry unit to perform an interface process between the color management module driver and a display driver.

The color matching system is mounted on, for example, an image display device, and performs color conversion adapted to color characteristics of a display device. The graphics interface, such as a graphics device interface (GDI) generates image creating commands for image data generated according to the operation of an application, and the display image data is generated based on the image creating commands. After the color conversion on the display image data is performed by the color management module, color space adjustment is performed based on a color attribute file representing the color characteristics of the display device. Then the display image data is supplied to the display device. The color management module includes the color management module driver to perform the color conversion on the display image data and the color management module entry unit to perform the interface process between the color management module driver and the display driver. With this configuration, the display image data adapted to the color reproducibility of the display device is displayed on the display device. Since the color conversion process for color matching is not performed by an application side but instead by the color management at a hardware-dependent portion, such as an OS, proper color matching is achieved without requiring any intervention from the application side.

In an exemplary aspect of the color matching system, the color matching system may include a display driver which generates the display image data based on the image creating commands, process the display image data based on the color attribute file corresponding to an output device after the display image data has been subjected to the color conversion by the color management module, and supply the processed display image data to the display device as output image data.

In another exemplary aspect of the color matching system, the graphics interface and the color management module perform processes based on a predetermined single standard color space. The color attribute file specifies the color characteristics of the display device for the predetermined single standard color space. With this configuration, since the color matching process is performed based on the predetermined single standard color space, it is unnecessary for the display driver to retain the ICC profile between the a plurality of standard color spaces and the display device.

In another exemplary aspect of the color matching system, the display driver has the color attribute file for each of a plurality of display devices. With this configuration, the color matching system can perform a proper color matching on the plurality of display devices even when the color matching system is used in combination with different display devices.

In another exemplary aspect of the color matching system, when the image creating commands instruct enlargement of the display image data, the display driver performs an enlargement process on the display image data after the display image data has been subjected to the color conversion by the color management module. With this configuration, when the enlargement process follows the display of image, process speed can be enhanced by performing the color matching process on the image data having a small size before the enlargement process.

In another exemplary aspect of the color matching system, when the image creating commands instruct reduction of the display image data, the display driver performs the color conversion by the color management module on the display image data after reduction. With this configuration, when the reduction process follows the display of an image, a process speed can be enhanced by performing the color matching process on the image data having a small size after the reduction process.

In addition, the image display device may include the color matching system, a display panel, and a display controller to perform control to display the output image data on the display panel.

According to another exemplary aspect of the present invention, a color matching method includes generating image creating commands based on instructions from an application, generating display image data based on the image creating commands, performing color conversion on the display image data based on predetermined color conversion reference data, processing the display image data based on a color attribute file corresponding to an output device after the display image data has been subjected to the color conversion in the color management process, and supplying the processed display image data to a display device as output image data.

In the same way as the above-mentioned color matching system, according to this color matching method, a graphics interface, such as GDI, generates the image creating commands for image data generated according to the operation of application, and the display image data is generated based on the image creating commands. The display image data is supplied to the display device after the display image data has been subjected to the color conversion by the color management module and the color space adjustment has been performed based on a color attribute file representing the color characteristics of the display device. With this configuration, the display image data adapted to the color reproduction of the display device is displayed on the display device. Since the color conversion process for color matching is performed not by an application side but instead by the color management at a hardware-dependent portion, such as an OS, a proper color matching is achieved without requiring any intervention from the application side.

According to yet another exemplary aspect of the present invention, a color matching program makes a computer function as a graphics interface to generate image creating commands based on instructions from an application, a color management module performs color conversion on display image data based on predetermined color conversion reference data, and a display driver generates the display image data based on the image creating commands, processes the display image data based on a color attribute file corresponding to an output device after the display image data has been subjected to the color conversion by the color management module, and supplies the processed display image data to a display device as output image data.

Such a color matching system can be implemented by executing the color matching program on the computer.

### BRIEF DESCRIPTION OF THE DRAWINGS

FIG. 1 is a schematic illustrating a schematic configuration of an image display device to which an exemplary aspect of the present invention is applied;

FIG. 2 is a schematic illustrating the software configuration of an image processing unit;

FIG. 3 is a flow chart of an image display processing including a color matching process; and

FIG. 4 is a flow chart of an image display process including enlargement or reduction of image data.

### DETAILED DESCRIPTION OF EXEMPLARY EMBODIMENTS

Hereinafter, the present invention will be described with reference to the accompanying drawings.

Image Display Device

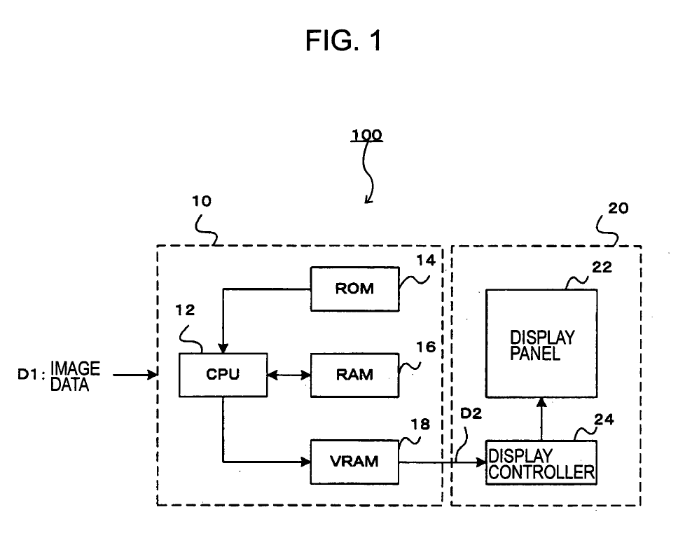

FIG. 1 is a schematic illustrating a configuration of an image display device 100 to which a color matching system of an exemplary aspect of the present invention is applied. As the display device 100, a terminal device with a display device, such as a mobile phone or a PDA may be used. However, it is to be understood that the application of the present invention is not limited to this.

The image display device 100 generally includes an image processing unit 10 and a display unit 20. The image processing unit 10 performs a color matching process on image data D1 supplied externally, or image data stored therein, to thereby generate display image data D2 to be supplied to the display unit 20. Specifically, the image processing unit 10 includes a CPU 12, a ROM 14, a RAM 16, and a VRAM 18.

OS for undertaking a basic control of the image processing unit 10, various application programs, etc., are stored in the ROM 14. Various application softwares, image data, etc., are stored in the RAM 16. In addition, a portion of the RAM 16 can be used as a working memory for a color matching process by the image processing unit 10. The VRAM 18 is an image memory in which the display image data D2 after the color matching process is performed by the image processing unit 10 is stored. The CPU 12 performs various processes and controls including the color matching process, which will be described in detail later, by executing the OS or application programs which are stored in the ROM 14.

The display unit 20 displays the display image data D2 supplied from the image processing unit 10 on a display panel 22. The display panel 22 may include a liquid crystal panel, for example, but is not limited to this. A display controller 24 generates a driving signal of pixels of the display panel 22 based on the display image data D2, and supplies the driving signals to the display panel 22 to thereby drive the display panel 22. Accordingly, an image corresponding to the display image data D2 supplied from the image processing unit 10 is displayed on the display panel 22.

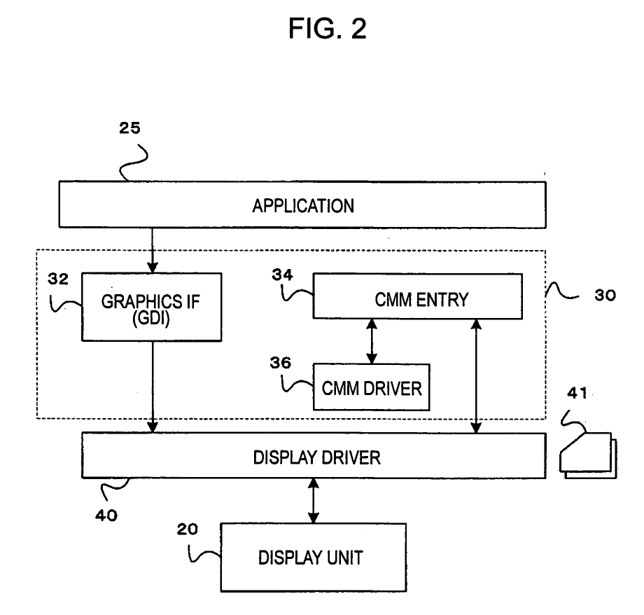

FIG. 2 is a schematic illustrating the software configuration of the image processing unit 10. The image processing unit 10 mainly includes an OS 30, an application 25, and a display driver 40 as its software configuration. Such a software configuration is implemented when the CPU 12 shown in FIG. 1 executes the OS or the applications which are stored in the ROM 14 or the RAM 16. In more detail, the application 25 is configured when the CPU 12 executes the applications. The OS 30 includes a graphics device interface (GDI) 32, a color management module (CMM) entry 34, and a CMM driver 36. The CMM entry 34 and the CMM driver 36 compose a CMM.

The GDI 32 is a software to control an output device, such as a display device or a printer for image display. In more detail, the GDI 32 generates image creating commands based on an output from the application 25 and supplies the commands to the display driver 40. The display driver 40 generates display image data based on the image creating commands.

The CMM composed of the CMM entry 34 and the CMM driver 36 performs color management of the display image data in response to the image creating commands generated by the GDI 32. The CMM driver 36 holds color conversion standard data in one standard color space, such as a sRGB space in the form of, for example, a 3-dimensional look table (LUT), and performs color conversion on the display image data supplied from the display driver 40 based on the color conversion standard data. The CMM entry 34 performs adjustment of data format between the display driver 40 and the CMM driver 36 and other interface processes. Specifically, the display image data outputted from the display driver 40 is supplied to the CMM driver 36 via the CMM entry 34. The CMM driver 36 performs the color conversion process required for the display image data and sends the color-converted display image data to the display driver 40 via the CMM entry 34.

The display driver 40 retains an ICC profile 41 which is a color attribute file according to color characteristics of the display panel 22 of the display unit 20. The ICC profile is a file to describe color attributes for each display device of the display panel and is prepared for each display panel. The display driver 40 performs the color conversion process and other processes to adapt the display image data on which a required color conversion process was performed by the CMM to the color characteristic of the display panel 22 using the ICC profile 41 corresponding to the display unit 20, and supplies the color-converted display image data to the display unit 20. Specifically, the display driver 40 performs a process to adapt the display image data to the color characteristics of the display unit 20 which is an output device, based on the ICC profile 41.

The display driver 40 can retain the ICC profile 41 for a plurality of display devices. Specifically, it can retain a plurality of ICC profiles corresponding to a plurality of display panels having different color characteristics, respectively. Accordingly, the image processing unit 10 can reproduce the color correctly as long as it uses the display panel 22 having a corresponding ICC profile retained in the display driver 40. Specifically, the image processing unit 10 can reproduce the color correctly even when different display units 20 having different color characteristics are combined with each other in various ways.

In the above configuration, the OS 30 and the display driver 40 are configured to perform processes in a single standard color space (for example, sRGB). Specifically, the GDI 32 receives a sRGB image from the application. At this time, if an image treated by the application 25 is a sRGB image, the application 25 may supply the sRGB image as it is to the GDI 32. If the image treated by the application 25 is an image in a color space other than the sRGB, the application (or middleware and so on) performs color matching to the color space on the image and supplies the color-matched image to the GDI 32.

Within the OS 30, the color management by the CMM is all performed on the sRGB. Specifically, the CMM driver 36 performs color conversion process for the color matching on the sRGB and supplies the color-converted display image data to the display driver 40. In this way, since the color management process within the OS 30 is performed on only the single standard color space, it is possible for the display driver 40 to retain only the ICC profile defining the relationship between the single standard color space and a color space of a display device. Accordingly, there is an advantage in that there is no need to hold ICC profiles for a plurality of standard color spaces for individual display devices.

In addition, the display driver 40 may be a software driver, or a hardware driver using an accelerator and so on.

Color Matching Process

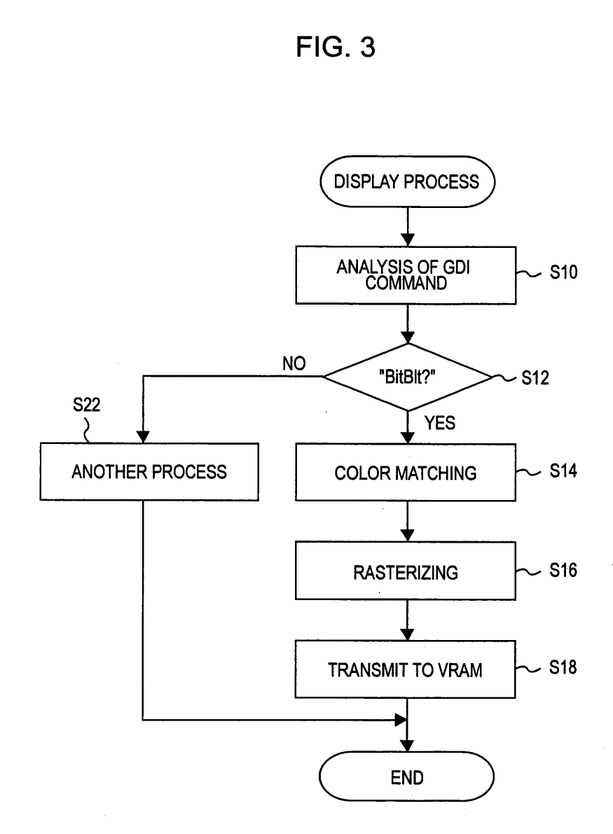

Next, an exemplary embodiment of an image processing including the color matching according to an exemplary aspect of the present invention will be described. FIG. 3 is a flow chart of an image processing. The image processing shown in FIG. 3 is basically performed by the display driver and the CMM shown in FIG. 2. Hereinafter, a case where a GDI command supplied from the GDI 32 is “BitBlt: (Bit)map (bl)ock (t)ransfer” will be described by way of an example. However, other commands will be processed in the same procedure as the GDI command.

To begin with, image data is transmitted from the application 25 to the GDI 32, and then the GDI 32 generates a GDI command to be supplied to the display driver 40. The display driver 40 receives and analyzes the GDI command (Step S10) and determines whether the GDI command is “BitBlt” or not (Step S12). Here, the GDI command “BitBlt” is a command having an argument of BitBlt (Bitmap, X1, Y1, X2, Y2), for example, which is referred to as a command to arrange bitmap data which is specified as Bitmap on a region defined by variables X1, Y1, X2, and Y2.

If the GDI command is “BitBlt” (Yes in Step S12), the display driver 40 supplies the generated display image data to the CMM driver 36 via the CMM entry 34, and the CMM driver 36 performs the color conversion for color matching on the supplied display image data (Step S14). Next, the display driver 40 rasterizes the color-converted display image data in order to expand it as raster data (Step S116), and then transmits the raster data to the VRAM 18 (Step S18).

If the GDI command is not “BitBlt” (No in Step S12), the display driver 40 performs processes on other GDI commands in the same way as in the above process, and then the image processing is ended.

Thus, the display image data (raster data) transmitted to the VRAM 18 is transmitted to the display unit 20 and is displayed on the display panel 22 under the control of the display controller 24.

In addition, the rasterizing in Step S16 is performed by a software process if the display driver 40 is a software driver and by a hardware process if the display driver 40 is a hardware driver. Here, in the color matching process of an exemplary aspect of the present invention, since the color matching is performed on only the image data before the image data is rasterized and transmitted to the VRAM, the same processing result can be obtained regardless of whether a rasterizing process after that is a hardware process or a software process. Particularly, in the image display device of an exemplary aspect of the present invention, when the color matching is performed on image data, such as a photographic image or an illustration, and then the image data is displayed on the display panel, as the display driver 40 and the CMM perform the color matching process on only the image data transmitted from the application according to the above flow chart, accurate display image data adapted to the color space of the display panel can be obtained.

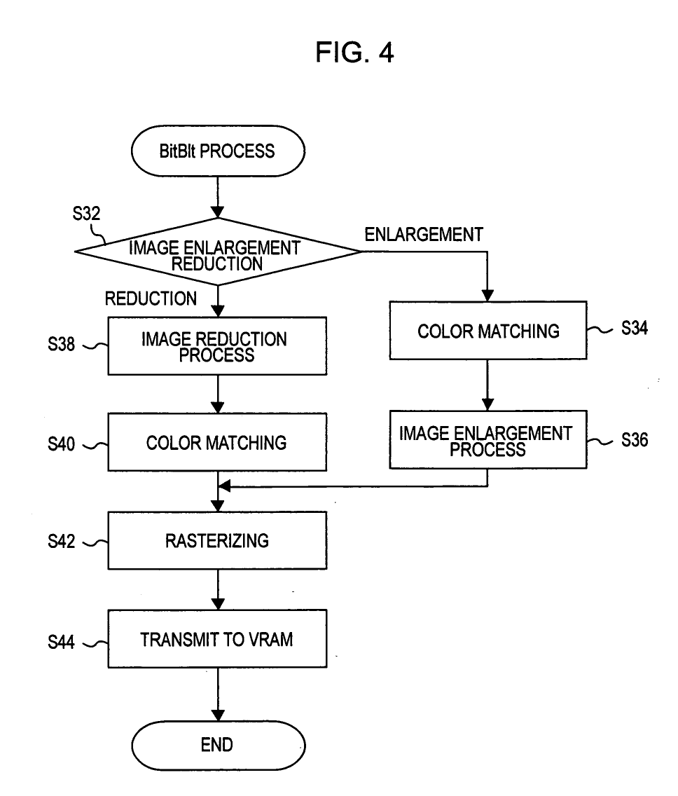

Next, an exemplary embodiment of a display process including enlargement or reduction of the image data will be described. FIG. 4 is a flow chart of a “BitBlt” process including the enlargement or reduction of the image data. This process is basically performed by the display driver 40 and the CMM in the same way as the process shown in FIG. 3.

There is a case where the size of a source image is enlarged or reduced to a specified size until the source image is finally rasterized as a BitBlt command and the rasterized image is transmitted to the VRAM. In the following example of the enlargement or reduction of the image in order to enhance a process speed of the color matching, a color matching process is performed in a step where image data has a small size.

To begin with, the display driver 40 receives the GDI command “BitBlt” from the GDI 32 and determines whether the image must be enlarged based on the command (Step S32). If it is determined that the image must be enlarged, the CMM composed of the CMM entry 34 and the CMM driver 36 performs the color matching on the image data before enlargement (Step S34). Then, the display driver 40 enlarges the color-converted image data (Step S36), rasterizes the enlarged image data (Step S42), and transmits the rasterized image data to the VRAM 18 (Step S44).

If it is determined that the image must be reduced, the display driver 40 first performs reduction of the image before color matching (Step S38). Then, the CMM performs color conversion for color matching on the reduced image data (Step S40). Thereafter, the display driver 40 rasterizes the color-converted image data (Step S42) and transmits the rasterized image data to the VRAM 18 (Step S44).

In this way, if there is a case where the image data must be enlarged or reduced, by performing the color matching on the image data in the step where the image data has a small size, load of the color matching process is alleviated, and accordingly, the image processing can be quickly performed. Such a process becomes feasible by performing the color matching process through the CMM or the display driver at the OS side, using the configuration of an exemplary aspect of the present invention shown in FIG. 2, instead of the application side.

The enlargement or reduction of the image data is performed in a case where image data having a certain size is displayed on a display device having a different display size or a case where image data is first displayed on a display device having a certain display size and then the displayed image data is enlarged or reduced if necessary.

As apparent from the above description, in the color matching process of an exemplary aspect of the present invention, since the color matching adapted to the color reproducibility space of the display device is performed in the hardware-dependent portion (OS side) to control devices instead of the application side, it is possible to perform a proper color matching without any intervention by the application developers or users of display devices. In addition, the color matching process is not frequently performed for creations of lines, characters, and rectangular shapes, or a faint out command, etc. on applications, unlike the image data, such as a natural picture. However, according to the color matching process of an exemplary aspect of the present invention, since creating colors for them are specified via the GDI, it is possible to provide good color reproducibility to the display device.

In addition, the color matching process of exemplary aspects of the present invention is applicable to various image data including images from input devices (for example, CCD camera), images from output device (for example, LCD), contents (images from external information providers), images photographed by digital cameras, etc.

1. A color matching system, that adopts image data from an application to use in a display driver, comprising:
a graphics interface to generate image creating commands based on instructions from the application; and
a color management module including a color management module driver to perform color conversion on display image data based on predetermined color conversion reference data and a color management module entry unit to perform an interface process between the color management module driver and the display driver.

2. The color matching system according to claim 1, the color management module generating the display image data based on the image creating commands and processing the display image data based on a color attribute file corresponding to an output device after the display image data has been subjected to the color conversion by the color management module.

3. The color matching system according to claim 1,
the graphics interface and the color management module performing processes based on a predetermined single standard color space, and the color attribute file specifying color characteristics of the display device for the predetermined single standard color space.

4. The color matching system according to claim 3,
the display driver having the color attribute file for each of a plurality of display devices.

5. The color matching system according to claim 1,
when the image creating commands instruct enlargement of the display image data, the display driver performs an enlargement process on the display image data after the display image data has been subjected to the color conversion by the color management module.

6. The color matching system according to claim 1,
when the image creating commands instructs reduction of the display image data, the display driver performs the color conversion by the color management module on the display image data after reduction.

7. An image display device, comprising:
the color matching system according to claim 1;
a display panel; and
a display controller to perform control to display the output image data on the display panel.

8. A color matching method, comprising:
generating image creating commands based on instructions from an application;
generating display image data based on the image creating commands;
performing color conversion on the display image data based on predetermined color conversion reference data; and
processing the display image data based on a color attribute file corresponding to an output device after the display image data has been subjected to the color conversion, and supplying the processed display image data to a display device as output image data.

9. A computer readable color matching program product containing a computer program, the computer program, comprising instructions to:
generate image creating commands based on instructions from an application;
perform color conversion on display image data based on predetermined color conversion reference data; and
generate the display image data based on the image creating commands, process the display image data based on a color attribute file corresponding to an output device after the display image data has been subjected to the color conversion, and supply the processed display image data to a display device as output image data.
